(19) United States
(12) Patent Application Publication
(10) Pub. No.: US 2013/0153029 A1
(43) Pub. Date: Jun. 20, 2013

(54) METHODS OF SUPPORTING A TRANSPARENT SUBSTRATE OF A THIN FILM PHOTOVOLTAIC DEVICE

(71) Applicants: Bradley Crume, Lakewood, CO (US); Max William Reed, Niwot, CO (US); Loucas Tsakalakos, Niskayuna, NY (US); Jeffrey Scott Erlbaum, Albany, NY (US); Troy Alan Berens, Evergreen, CO (US); Jeffrey Todd Knapp, Golden, CO (US); Venkata Sai Rahul Chandra Abbaraju, Denver, CO (US)

(72) Inventors: Bradley Crume, Lakewood, CO (US); Max William Reed, Niwot, CO (US); Loucas Tsakalakos, Niskayuna, NY (US); Jeffrey Scott Erlbaum, Albany, NY (US); Troy Alan Berens, Evergreen, CO (US); Jeffrey Todd Knapp, Golden, CO (US); Venkata Sai Rahul Chandra Abbaraju, Denver, CO (US)

(73) Assignee: PRIMESTAR SOLAR, INC., Arvada, CO (US)

(21) Appl. No.: 13/326,861

(22) Filed: Dec. 15, 2011

(51) Int. Cl. H01L 31/0203; B29C 65/54

(52) U.S. Cl. 136/259; 156/285

(57) ABSTRACT

Methods are generally provided for adhering a support insert within a connection aperture defined in an encapsulating substrate of a photovoltaic device that has a first lead. The connection aperture generally has a perimeter defined by an aperture wall of the encapsulating substrate. The method can, in one particular embodiment, include threading the first lead through the connection aperture; and positioning a support insert within the connection aperture such that the first lead is still able to extend through the connection aperture. The support insert can generally define a channel within its construction that extends from a channel opening in the support insert to an exit port. An adhesive composition can be injected into the channel opening such that a first amount of the adhesive composition flows through the channel and out of the exit port to bond the support insert within the connection aperture.

### FIELD OF THE INVENTION

The subject matter disclosed herein relates generally to photovoltaic devices including a support insert positioned in a connection aperture of the encapsulating substrate to mechanically support the transparent substrate in the area of the connection aperture.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. The junction of the n-type layer (e.g., CdS) and the p-type layer (e.g., CdTe) is generally responsible for the generation of electric potential and electric current when the CdTe PV module is exposed to light energy, such as sunlight. A transparent conductive oxide (“TCO”) layer is commonly used between the window glass and the junction forming layers to serve as the front electrical contact on one side of the device. Conversely, a back contact layer is provided on the opposite side of the junction forming layers and is used as the opposite contact of the cell.

An encapsulation substrate is positioned on the opposite side of the device from the window glass to encase the thin film layers. The encapsulation substrate also serves to mechanically support the window glass of the PV device. However, the encapsulation substrate typically contains a hole that enables connection of the photovoltaic device to lead wires for the collection of the DC electricity created by the PV device. The presence of the hole in the encapsulation substrate can induce a weak point in the device. For example, the PV device may be particularly susceptible to hail damage (e.g., cracking) in the window glass in the area at or near the encapsulation hole. This weakness can be exaggerated when the window glass is made from a specialty glass and/or a relatively thin glass.

As such, a need exists to inhibit and prevent cracking in the window glass of a PV device, particularly in the area where a hole is located in the encapsulation substrate.

### BRIEF DESCRIPTION OF THE INVENTION

Aspects and advantages of the invention will be set forth in part in the following description, or may be obvious from the description, or may be learned through practice of the invention.

Methods are generally provided for adhering a support insert within a connection aperture defined in an encapsulating substrate of a photovoltaic device that has a first lead. The connection aperture generally has a perimeter defined by an aperture wall of the encapsulating substrate. The method can, in one particular embodiment, include threading the first lead through the connection aperture; and positioning a support insert within the connection aperture such that the first lead is still able to extend through the connection aperture. The support insert can generally define a channel within its construction that extends from a channel opening in the support insert to an exit port. An adhesive composition can be injected into the channel opening such that a first amount of the adhesive composition flows through the channel and out of the exit port to bond the support insert within the connection aperture.

In one particular embodiment, for example, the adhesive composition can be injected into the channel opening in the support insert such that a first portion of the adhesive composition flows through the channel in the support insert out of a first reservoir opening and into the first reservoir to bond the first platform of the support insert to the back surface of the encapsulating substrate.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a cross-sectional view of an exemplary thin film photovoltaic device according to one embodiment;

FIG. 2 shows a general schematic of an exemplary photovoltaic device for use with the support insert of FIGS. 3-13;

FIG. 3 shows a perspective view of an exemplary support insert for use with the thin film photovoltaic devices of FIG. 1 or 2;

FIG. 4 shows a perspective view of another exemplary support insert for use with the thin film photovoltaic devices of FIG. 1 or 2;

FIG. 5 shows a perspective view of yet another exemplary support insert for use with the thin film photovoltaic devices of FIG. 1 or 2;

FIG. 6 shows a cut-away view of the exemplary support insert of FIG. 5 in relation to the first and second leads;

FIG. 7 shows perspective view yet another exemplary support insert for use with the thin film photovoltaic devices of FIG. 1 or 2;

FIG. 8 shows a perspective view of yet another exemplary support insert for use with the thin film photovoltaic devices of FIG. 1 or 2;

FIG. 9 shows a cut-away view of the exemplary photovoltaic device of FIG. 8 with the encapsulation substrate and leads;

FIG. 10 shows a perspective view of yet another exemplary support insert for use with the thin film photovoltaic devices of FIG. 1 or 2;

FIG. 11 shows a perspective view of yet another exemplary support insert for use with the thin film photovoltaic devices of FIG. 1 or 2;

FIG. 12 shows a perspective view of yet another exemplary support insert for use with the thin film photovoltaic devices of FIG. 1 or 2;

FIG. 13 shows a perspective view of yet another exemplary support insert for use with the thin film photovoltaic devices of FIG. 1 or 2;

FIG. 14 shows a general schematic of an exemplary photovoltaic device for use with the support insert of FIGS. 15-17;

FIG. 15 shows a bottom perspective view of an exemplary support insert for use with the thin film photovoltaic devices of FIG. 1 or 14;

FIG. 16 shows a perspective view of another exemplary support insert for use with the thin film photovoltaic devices of FIG. 1 or 14;

FIG. 17 shows a bottom perspective view of the exemplary support insert of FIG. 16; and,

FIG. 18 shows a general schematic of another exemplary photovoltaic device with a support insert and an epoxy plug;

FIG. 19 shows a general schematic of an exemplary photovoltaic device with an epoxy plug;

FIG. 20 shows a perspective view of an exemplary back plate for use with the thin film photovoltaic device of FIG. 19; and,

FIG. 21 shows a general schematic of another exemplary photovoltaic device with an epoxy plug.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise specifically noted. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

A thin film photovoltaic device is generally provided having a support insert positioned within a connection aperture of the encapsulation substrate (e.g., back glass) to mechanically support the transparent substrate (e.g., window glass) in the area of the connection aperture. The support insert can be generally configured such that a first lead (and optionally a second lead) is able to extend through the connection aperture while the support insert in place within the connection aperture. As such, the support insert can provide structural support for the transparent substrate while still enabling the connection aperture to be utilized to electrically connect the lead(s) of the PV device to an electrical collection apparatus (e.g., a junction box).

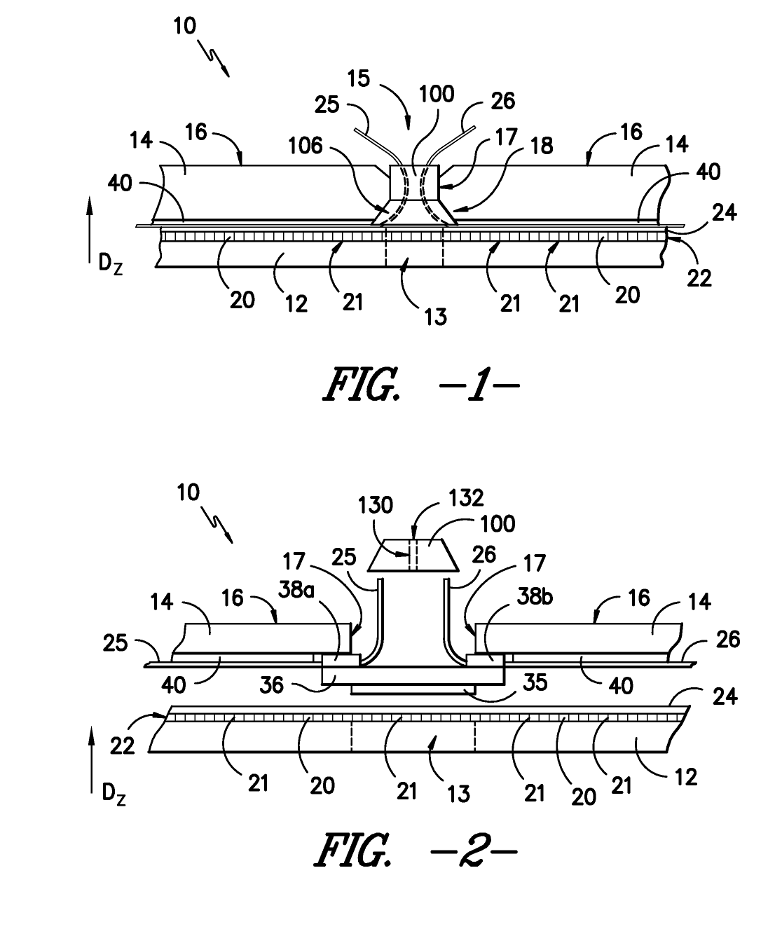

FIG. 1 shows a cross-sectional view of an exemplary thin film photovoltaic device 10 utilizing a support insert 100 to mechanically support the transparent substrate 12 in an area 13 of the transparent substrate 12 that is opposite to the connection aperture 15 defined by the encapsulation substrate 14. Additionally, the support insert 100 is configured such that a first lead 25 and an optional second lead 26 are able to extend through the connection aperture 15 of the encapsulation substrate 14 while the support insert 100 is in place within the connection aperture 15. The first and second leads 25, 26 are generally configured to collect the DC current generated by the plurality of photovoltaic cells 20 in the device 10.

The support insert 100 can be constructed from any suitable material that provides sufficient stiffness to mechanically support the transparent substrate 12 in the area 13 opposite to the connection aperture 15. For example, in certain embodiments, the support insert 100 can be constructed from a molded plastic material, a molded hard rubber material, or a combination thereof.

The connection aperture 15 can generally have a perimeter defined by an aperture wall 17 of the encapsulation substrate 14. In one embodiment, the aperture wall 17 can be coupled to the support insert 100. For instance, the aperture wall 17 can be beveled or chamfered, and the support insert 100 be configured to couple with the aperture wall 17.

An adhesive can, in certain embodiments, be positioned to bond the support insert 100 to the aperture wall 17 of the encapsulation substrate 14 and/or to bond the support insert 100 to the underlying layers on the transparent substrate 12. In one particular embodiment, the support insert 100 can define an adhesive channel within its construction that is configured to supply adhesive from an exposed channel opening to the aperture wall of the connection aperture.

The support insert 100 shown in FIGS. 1, 2, 14, and 18 can have any suitable design for mechanically supporting the transparent substrate 12 in the area 13 opposite to the connection aperture 15 of the encapsulation substrate 14. In the embodiments shown, the connection aperture 15 generally has a circular shape, and likewise, the support insert 100 generally has a circular shape. However, it is understood that other shapes can be utilized as desired (e.g., square, oval, slot-like, etc.).

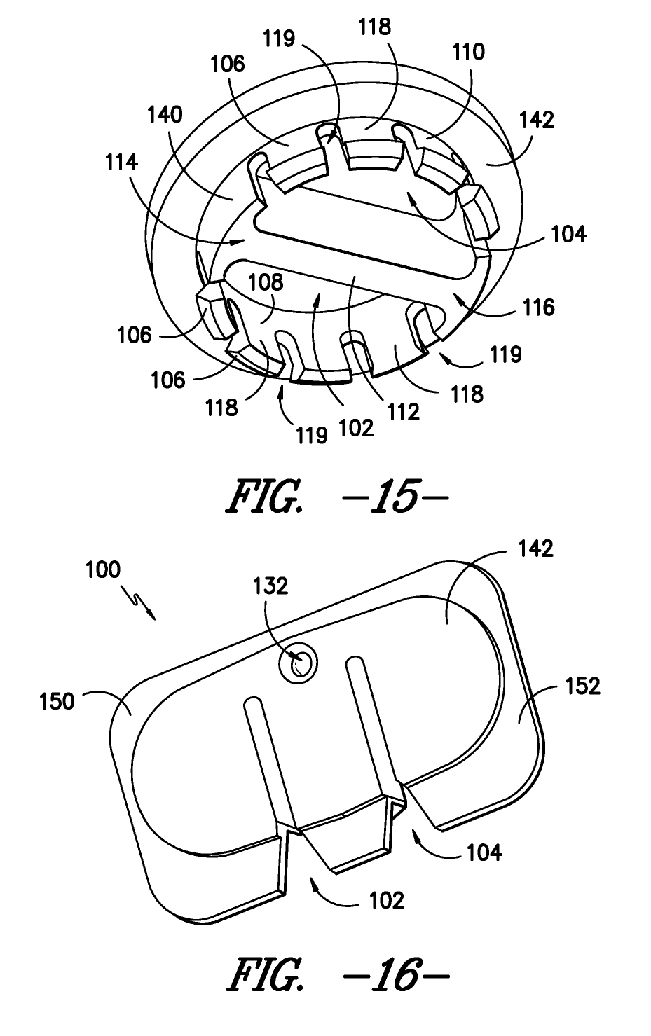

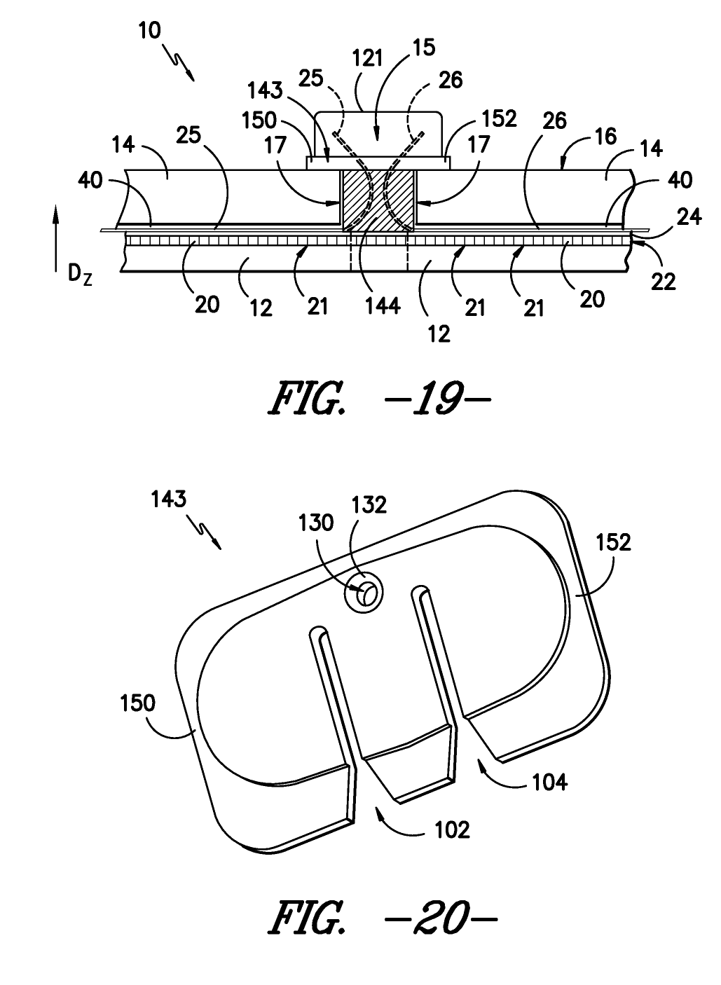

Not only can the support insert 100 have a variety of designs, but also the support insert 100 can have differing thicknesses in the z-direction. For example, the support insert 100 can, in one embodiment, have a support thickness and the encapsulation substrate 14 has a substrate thickness in the z-direction D_{z}, with the support thickness being equal to or less than the substrate thickness such that the support insert 100 does not extend beyond a back surface 16 defined by the encapsulation substrate 14. Alternatively, as shown in the exemplary embodiment of FIGS. 14 and 18, the support insert 100 can define a plug portion 200 configured to be positioned within the connection aperture 15 and a flange 142 that extends over the back surface 16 of the encapsulation substrate 14.

Exemplary support inserts 100 are discussed in greater detail below. However, it is again noted that features of one embodiment may be combined with features of another embodiment to form an additional embodiment, even if not explicitly shown in the exemplary embodiments of the Figures.

First, FIGS. 3-13 show exemplary support inserts 100 having a support thickness that is equal to or less than the substrate thickness such that the support insert 100 does not extend beyond the back surface 16 defined by the encapsulation substrate 14.

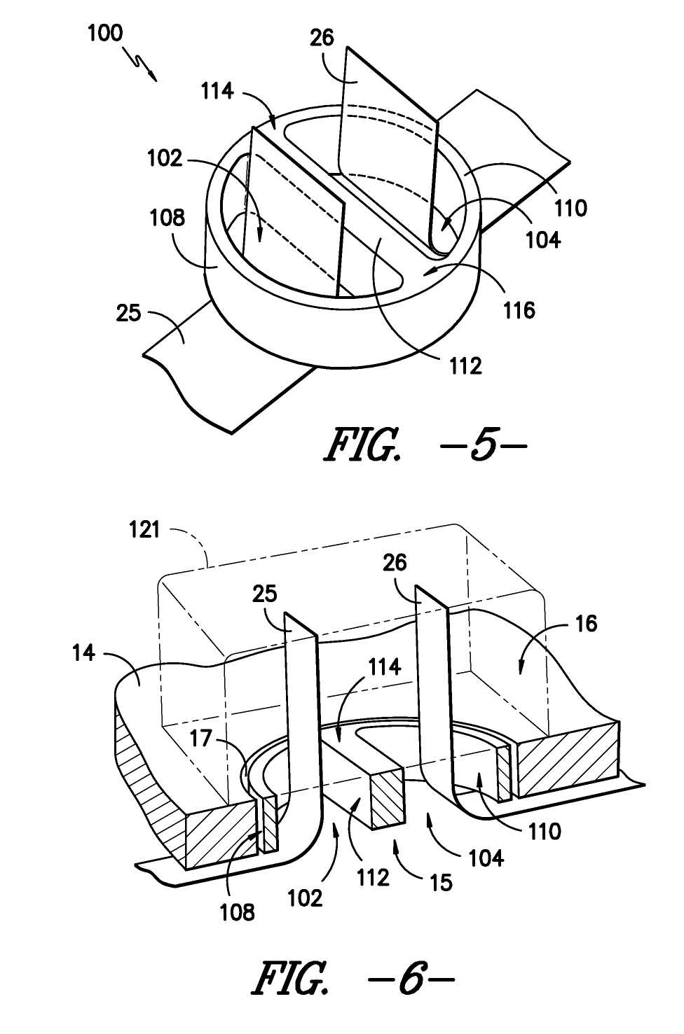

Referring to FIGS. 3 and 4, the support insert 100 can define a first slot 102 and a second slot 104 that allow, respectively, the first lead 25 and the second lead 26 to extend therethrough. As shown, the first slot 102 and the second slot 104 are open-ended in the support insert 100, which can allow the first lead 25 and the second lead 26 to be pulled into their respective slots 102, 104 without threading.

In the embodiment of FIGS. 3-4, the support insert 100 also defines a lip 106, which is slightly larger (in diameter) than the smallest diameter of the connection aperture 15 (e.g., about 1% to about 10% larger). The lip 106 is configured to couple with a groove 18 defined in the aperture wall 17 of the encapsulation substrate 14. The first and second slots 102, 104 can, in this configuration, not only provide access for the first and second leads 25, 26, respectively, but also can provide flexibility in its circumference to allow for the insertion of the support insert 100 into the connection aperture 15 even with the lip 106 present. That is, the flexibility in its circumference particularly facilitates the compression of the lip 106 to a sufficient degree that permits insertion thereof into and through the connection aperture 15. That same flexibility, in turn, permits the compressed lip 106 to stay in place at that point and retain the support insert 100 within the connection aperture.

Referring to the embodiment of FIG. 4, the support insert 100 defines a first curved exterior beam 108, a second curved exterior beam 110, and an interior beam 112 that are connected to each other at a location 114. The interior beam 112 extends between the first curved exterior beam 108 and the second curved exterior beam 110 such that the first slot 102 is defined between the first curved exterior beam 108 and the interior beam 112 and the second slot 104 is defined between the second curved exterior beam 110 and the interior beam 112. In the embodiment shown, the first and second curved exterior beams 108, 110 have an arcuate shape, which is particularly useful in combination with a connection aperture 15 having a circular shape. Thus, the first and second curved exterior beams 108, 110 can each define a semi-circular opening, helping to minimize the amount of material used for the support insert 100 and/or to increase the opening space through which each of the first and second leads 25, 26 can extend.

FIGS. 5-7 show an embodiment of the support insert 100 that defines a first slot 102 and a second slot 104 that are closed-ended. That is, while the first slot 102 and second slot 104 allow, respectively, for the first lead 25 and the second lead 26 to extend therethrough, the first slot 102 and the second slot 104 are closed-ended such that the first lead 25 and the second lead 26 can be threaded into and through the respective slots 102, 104. Such an embodiment can provide additional stiffness to the support insert 100 by removing any flexibility due to open-ended slots.

The support insert 100 defines a first curved exterior beam 108, a second curved exterior beam 110, and an interior beam 112 that are connected to each other at a first location 114 and at a second location 116. The interior beam 112 extends between the first curved exterior beam 108 and the second curved exterior beam 110 such that the first slot 102 is defined between the first curved exterior beam 108 and the interior beam 112 and the second slot 104 is defined between the second curved exterior beam 110 and the interior beam 112. Thus, the first and second slots 102, 104 are closed-ended to provide support to the transparent substrate 12 around the entire circumference of the area 13 and through the middle of the area 13. Further, like the embodiment shown in FIG. 4, the first and second slots 102, 104 are substantially semi-circular to help maximize the space available through which each of the first and second leads 25, 26 may be fed, respectively.

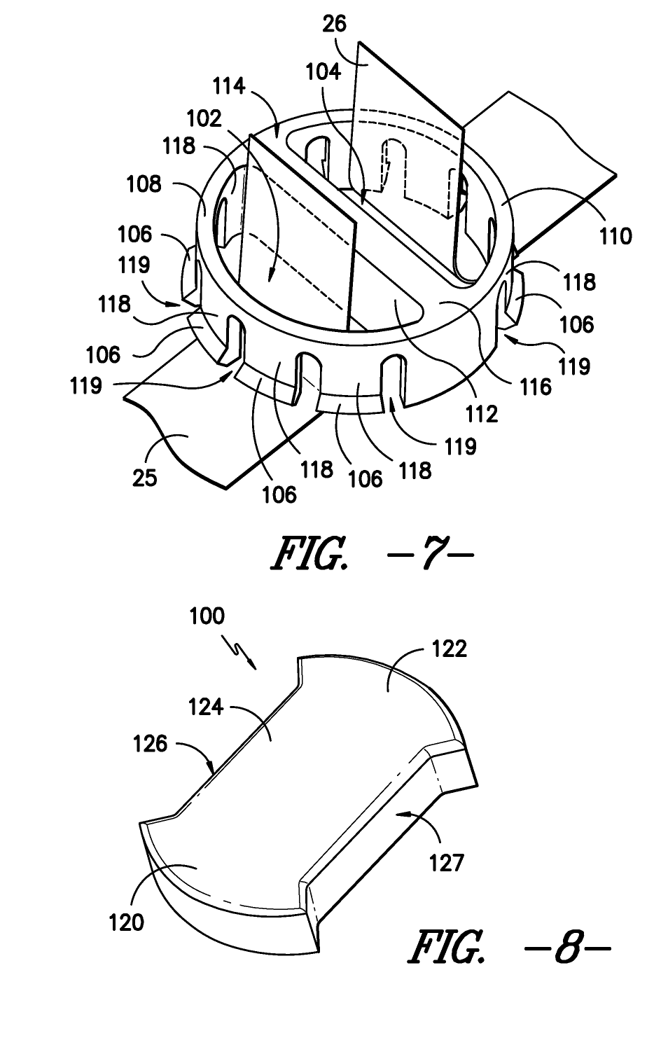

The embodiments of FIGS. 5-6 define a substantially straight surface (i.e., without a lip) and can be particularly useful with encapsulation substrate 14 that define an aperture wall 17 completely oriented in the z-direction D_{z} (i.e., without a groove). Such an orientation can be particularly useful when a junction box 121 or other backing member is mounted on the back surface 16 of the encapsulation substrate 14 over the connection aperture 15, as shown in FIG. 6. The junction box 121 can be electrically connected to the leads 25, 26 and can be configured so as to provide additional structural support to help keep the support insert 100 within the connection aperture 15.

In the embodiment shown in FIG. 7, the support insert 100 defines a lip 106, collectively defined on tabs 118. The tabs 118 are generally configured to extend into the connection aperture 15 and couple with a groove 18 in the aperture wall 17. The tabs 118 are separated from one another by the spacer slots 119 to allow flexibility of the tabs 118 such that the support insert 100 can be “snapped” into the connection aperture 15 that defines a groove 18 in the aperture wall 17.

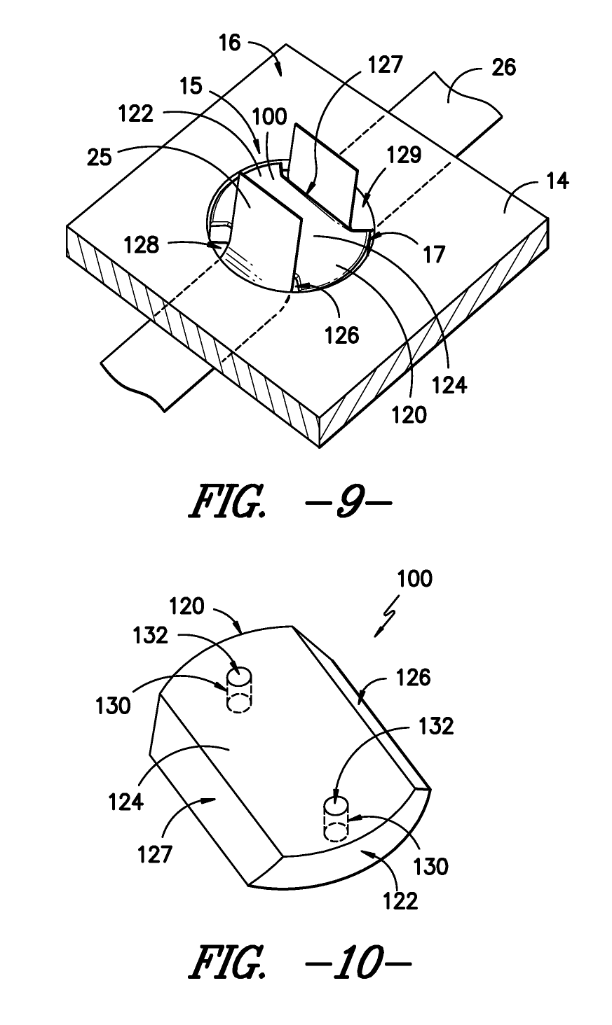

FIGS. 8-11 show an embodiment of the support insert 100 the support insert that defines two arc segments 120, 122 connected to each other via a midsection 124 that generally defines a first side 126 and a second side 127. The support insert 100 can be configured to define a first channel 128 between the first side 126 of the midsection 124 and the aperture wall 17 and a second channel 129 between the second side 127 and the connection aperture 15. As such, the first lead 25 can extend through the first channel 128, and the second lead 26 can extend though the second channel 129.

This configuration can substantially fill the connection aperture 15 to provide structural support throughout the area 13 of the transparent substrate 12. Additionally, this embodiment can allow for relatively easy insertion of the support insert 100 into the connection aperture 15 without threading of the leads 25, 26 into a slot. For example, the leads 25, 26 can be inserted through the connection aperture 15 and wrapped back onto the back surface 16 of the encapsulation substrate 14. Then, the support insert 100 can be inserted into the connection aperture 15 and positioned such that the first channel 128 formed between the first side 126 of the midsection 124 and the aperture wall 17 is located where the first lead 25 is already situated and the second channel 129 formed between the second side 127 and the connection aperture 15 is located where the second lead 26 is already situated.

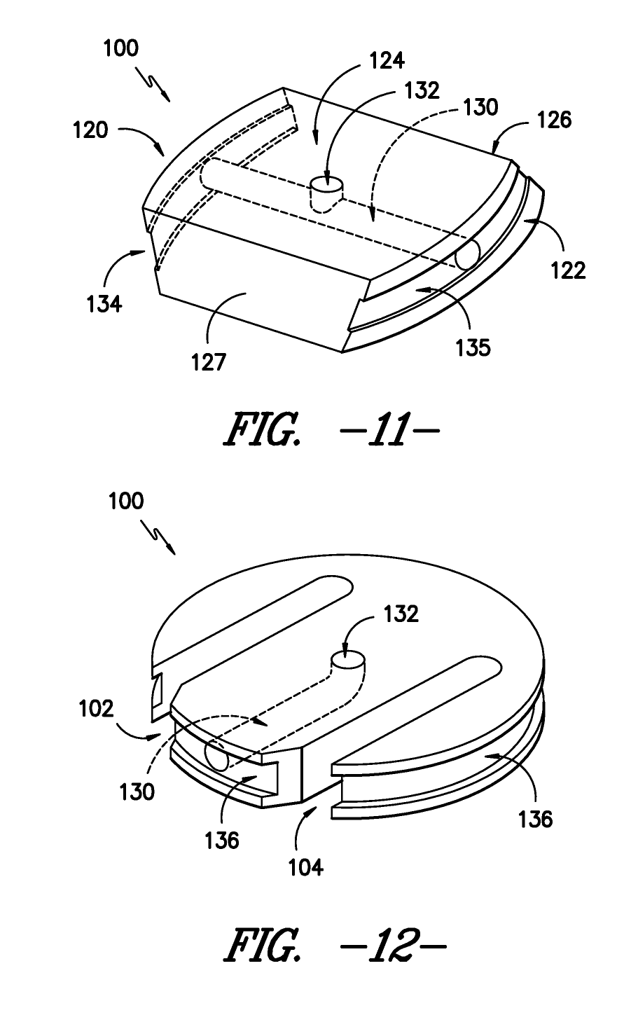

The support insert 100 can be configured such that the channels 128, 129 are sized according to the size of the leads 25, 26, respectively. For example, the embodiment of FIGS. 8-9 show that the two arc segments 120, 122 extend beyond the width of the midsection 124, while the embodiment of FIG. 10 shows that the midsection having substantially the same width as the two arc segments 120, 122. In one embodiment as shown in FIGS. 8-9, the aperture wall 17 and the sides 126, 127 are substantially oriented in the z-direction D_{z}. Alternatively, the embodiment shown in FIG. 10, the sides 126, 127 can be angled with respect to the z-direction D_{z}.

The support insert 100 shown in FIGS. 10-11 also defines an adhesive channel 130 within its construction that is configured to supply adhesive from an exposed channel opening 132 through the support insert 100 into some area of the connection aperture 15. For example, as shown in FIG. 10, the adhesive channel 130 can extend from the exposed channel opening 132 through the support insert 100. In this manner, the adhesive channel 130 can supply adhesive to be positioned between the support insert 100 and the underlying layers of the device 10 such that the support insert 100 can be bonded thereto. Alternatively, as shown in FIG. 11, the adhesive channel 130 can be configured to supply adhesive from the exposed channel opening 132 to the aperture wall 17 to bond the support insert 100 thereto. The embodiment of FIG. 11 also shows that the support insert 100 defines adhesive reservoirs 134, 135 along the sides of two arc segments 120, 122 such that the adhesive can bond the two arc segments 120, 122 to the aperture wall 17. The reservoirs 134, 135 are generally defined by the indented space formed in the side of their respective arc segments 120, 122.

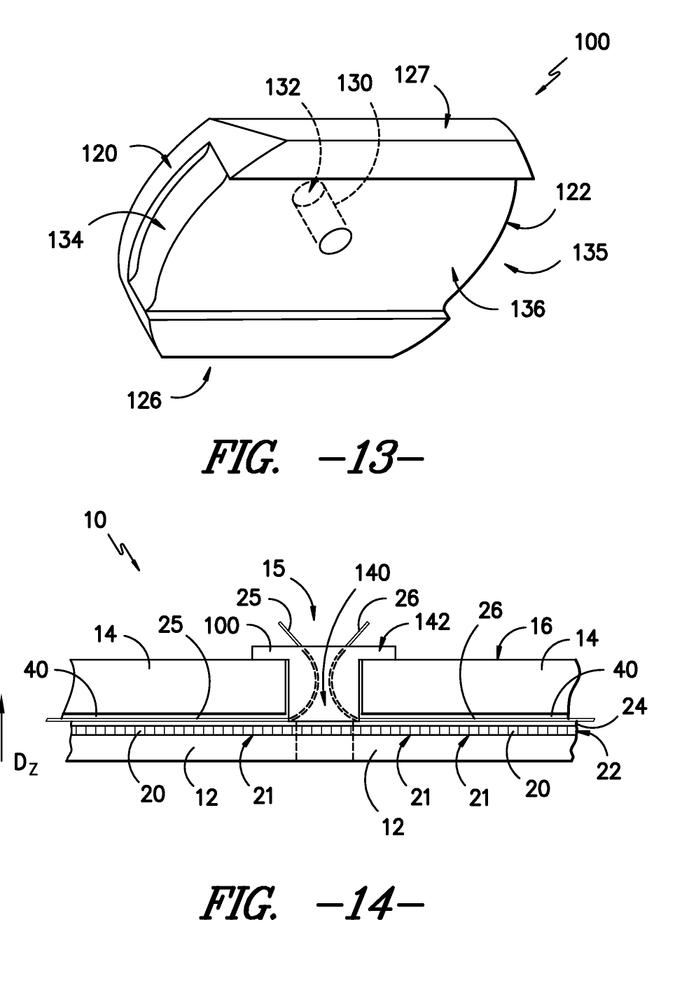

FIG. 12 shows an embodiment of the support insert 100 that is similar to the configuration shown in FIG. 3. Specifically, the support insert 100 defines an open-ended first slot 102 and an open-ended second slot 104 that allow, respectively, the first lead 25 and the second lead 26 to extend therethrough. The support insert 100 also defines an adhesive reservoir 136 about the circumference of the support insert 100 such that the adhesive can be inserted thereto to bond the support insert to the aperture wall 17. The reservoir 136 is generally defined by the indented space formed in the side of the support insert 100.

FIG. 13 shows yet another embodiment of the support insert 100, which is similar to the configuration shown in FIG. 10. However, in this embodiment, the support insert 100 defines an adhesive reservoir 136 between the support insert 100 and the underlying layers of the device 10 within the connection aperture 15 such that the adhesive can be inserted into the connection aperture. Additionally, the support insert 100 defines adhesive reservoirs 134, 135 along the sides of two arc segments 120, 122 such that the adhesive can bond the two arc segments 120, 122 to the aperture wall 17 (similarly to the embodiment of FIG. 11). Thus, the adhesive can be inserted through the exposed channel opening 132 and into the reservoir 136 through the adhesive channel 130, and allowed to flow into the reservoirs 134, 135 to bond the support insert to the aperture wall 17.

Second, FIGS. 14 and 18 show exemplary devices 10 having a support insert 100 that defines a plug portion 140 configured to be positioned within the connection aperture 15 and a flange 142 that extends over the back surface 16 of the encapsulation substrate 14.

The plug portion 140 can, in one embodiment, extend through the connection aperture 15 and contact an underlying layer on the transparent substrate 12, as shown in FIG. 14.

In an alternative embodiment, the plug portion 140 can extend into only a portion of the connection aperture 15, as shown in FIG. 18. For example, the plug portion can extend a distance of about 5% to about 75% of the depth of the connection aperture 15 (e.g., about 5% to about 50%), where the depth is measured as the distance from the back surface 16 to the transparent substrate 12. In the embodiment of FIG. 18, an adhesive plug 144 can be positioned of formed (e.g., first deposited as a liquid and then hardened via, e.g., curing) between the plug portion 140 of the support insert 100 and the transparent substrate 12.

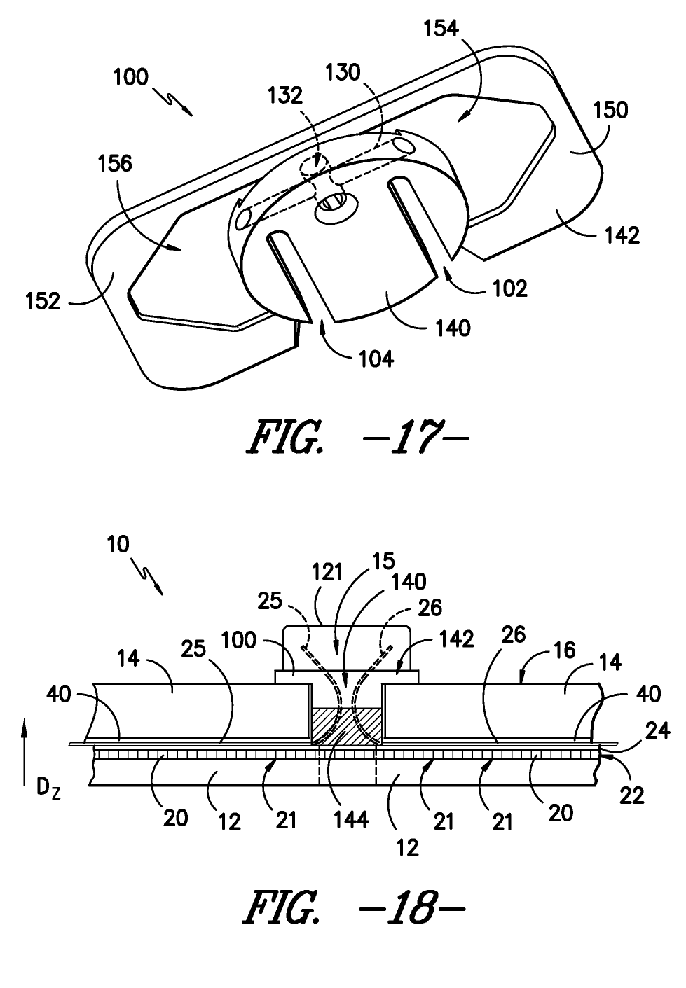

No matter then particular depth, the plug portion 140 can have any suitable design, including but not limited to the designs discussed above with respect to FIGS. 3-13. For example, the embodiment of FIG. 15 has a plug portion 140 that generally corresponds to that shown in FIG. 7 and is discussed in greater detail above. Likewise, the embodiment shown in FIGS. 16-17 has a plug portion 140 similar to that shown in FIGS. 3 and/or 12 in that the first and second slots 102, 104 are open-ended.

Without wishing to be bound by any particular theory, it is believed that the flange 142 can help to dissipate energy to the encapsulation substrate 14 from a force (e.g., hail) applied to the window surface of the transparent substrate 12 in the area 13 corresponding to the connection aperture 15. As such, instead of relying on solely on the plug portion 140 to provide structural support to the transparent substrate 12 within the connection aperture 15, the flange 142 can help position and transfer energy from the transparent substrate 12 to the encapsulation substrate 14. Further, the flange 142 can effectively add to the stiffness of the overall device 10 proximate to the connection aperture 15, reducing the amount of bending and/or flexure that may occur upon impact (e.g., due to hail) in that region. The flange 142 can extend any suitable distance on the back surface 16 of the encapsulation substrate 14 as desired to transfer energy thereto.

The flange 142 can, in one embodiment, extend perimetrically from the plug portion 140 of the support insert 100 to extend fully around the connection aperture 15. For example, FIG. 15 shows a flange 142 extending perimetrically from the plug portion 140. The support insert 100 shown in FIGS. 16-17 has a flange 142 that defines a first platform 150 and a second platform 152 that respectively extend away from diametrically opposed sides of the plug portion 140 and over the back surface 16 of the encapsulation substrate 14.

In the embodiment of FIGS. 16-17, the first platform 150 and second platform 152 can define a first reservoir 154 and a second reservoir 156. The first reservoir 154 is generally defined between the first platform 150 and the back surface 16 of the encapsulation substrate 14, and the second reservoir 156 is generally defined between the second platform 152 and the back surface 16 of the encapsulation substrate 14. An adhesive can be positioned within the first and second reservoirs 154, 156 (e.g., as a pre-placed preform or via delivery of an initially liquid adhesive) to bond, respectively, the first and second platforms 150, 152 to the back surface 16 of the encapsulation substrate 14.

The support insert 100 can also define an adhesive channel 130 within its construction to supply the adhesive from an exposed channel opening 132 to the first reservoir 154 and second reservoir 156 after insertion of the plug portion 140 into the connection aperture 15. The adhesive channel 130 can also be configured to provide adhesive through the plug portion 140 to bond the plug portion 140 to the underlying layers on the transparent substrate 12 of the device 10. For example, referring to FIG. 18, an adhesive plug 144 can be formed after insertion of the plug portion 140 into the connection aperture through the adhesive channel 130. The adhesive plug 144 can not only bond the plug portion 140 to the device 10, but also provide structural support to the transparent substrate 12 in the area 13, corresponding to the connection aperture 15 on the encapsulation substrate 14.

For example, the adhesive channel 130 can split within the construction of the support insert 100 such that the channel extends from the channel opening 132 to the first reservoir opening and a second reservoir opening such that injecting the adhesive composition into the channel opening results in a first reservoir portion of the adhesive composition flowing through the channel 130 and out of the first reservoir opening such that the first reservoir portion bonds the first platform 150 to the back surface 16 of the encapsulation substrate 14 and a second reservoir portion flowing through the channel 130 and out of the second reservoir opening such that the second reservoir portion bonds the second platform 152 to the back surface 16 of the encapsulation substrate 14.

The flange 142 (e.g., the first platform 150 and the second platform 152) can, in one embodiment, be configured to couple with a junction box 121, as shown in FIG. 18. The junction box 121 can be positioned over the support insert 100 and connected to the first and second leads 25, 26.

In an alternative embodiment, an adhesive plug 144 can be positioned within the connection aperture 15 and can substantially fill the entire area of the connection aperture 15, as shown in the embodiments of FIGS. 19 and 21. For example, the adhesive plug 144 can fill at least 90% of the space defined between the aperture walls 17, such as about 95% to 100% of the space defined between the aperture walls 17.

In one particular embodiment, the adhesive plug 144 can be substantially formed from an epoxy material (i.e., a cured epoxy plug), although other materials may be present in smaller quantities in the plug 144. In one particular embodiment, the epoxy resin can be polyepoxide, which is a thermosetting polymer formed from reaction of an epoxide resin with polyamine hardener. Most common epoxy resins are produced from a reaction between epichlorohydrin and bisphenol-A, though the latter may be replaced by similar chemicals. The hardener can be a polyamine monomer, for example triethylenetetramine (TETA). When these compounds are mixed together, the amine groups react with the epoxide groups to form a covalent bond upon curing. Each NH group can react with an epoxide group, so that the resulting polymer is heavily crosslinked, and is thus rigid and strong. Thus, the adhesive plug 144 can provide mechanical support to the transparent substrate 12.

FIG. 19 shows an exemplary embodiment where the adhesive plug 144 is used in conjunction with a back plate 143 positioned over the connection aperture 15 and extending onto the back surface 16 of the encapsulation substrate 14. The back plate 143 can be adhered not only to the adhesive plug 144, but also to the back surface 16 of the encapsulation substrate 14 in order to help dissipate energy transferred through the adhesive plug 144 to the back plate 143.

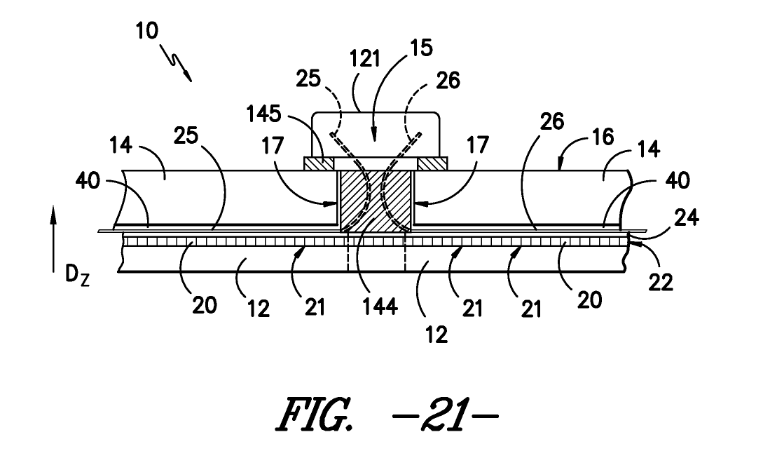

FIG. 20 shows one particular embodiment of a back plate 143 that is similar in design to the support insert 100 of FIGS. 16-17 in that a first platform 150 and a second platform 152 extend over the back surface 16 and are bonded thereto. For example, the back plate 143 can define adhesive reservoirs 154, 156 as shown with respect FIG. 17. Additionally, the back plate 143 can define first and second slots 102, 104 to allow the first and second leads 25, 26 to pass therethrough, respectively. Optionally, an adhesive channel 130 can be positioned through the back plate 143 to allow adhesive to be inserted (at the channel opening 132) into the underlying connection aperture 15 and cured to form the adhesive plug 144.

FIG. 21 shows an exemplary embodiment where the adhesive plug 144 is used in conjunction with a back washer 145 bonded around the edges of the connection aperture 15 and extending onto the back surface 16 of the encapsulation substrate 14. The back washer 145 can be adhered optionally to the adhesive plug 144 (if a portion of the back washer 145 extends over the connection aperture 15). No matter, the back washer 145 is adhered to the back surface 16 of the encapsulation substrate 14 in the area surrounding the connection aperture 15. As such, the back washer 145 can provide mechanical support to the encapsulation substrate 14 in the area around the connection aperture 15, while the adhesive plug provides mechanical support to the transparent substrate 14 opposite from the connection aperture 15. Thus, the back washer 145 can help dissipate energy across the encapsulation substrate 14 when energy is transferred through the adhesive plug 144 to the aperture walls 17 of the connection aperture 15. As shown, the back washer 145 can define a ring that extends perimetrically around the connection aperture 15 on the back surface 16 of the encapsulation substrate 14. In this embodiment, the leads 25, 26 can be threaded through the center hole defined by the back washer 145.

Referring again to FIGS. 1, 2, 14, 18, 19, and 21, the transparent substrate 12 can be, in one embodiment, a “superstrate,” as it can be the substrate on which the subsequent layers are formed even though it faces upward to the radiation source (e.g., the sun) when the photovoltaic device 10 is in use. The transparent substrate 12 can be a high-transmission glass (e.g., high transmission borosilicate glass), low-iron float glass, or other highly transparent glass material. The glass is generally thick enough (e.g., from about 0.5 mm to about 10 mm thick) to provide support for the subsequent film layers, and is substantially flat to provide a good surface for forming the subsequent film layers. In one embodiment, the glass 12 can be a low iron float glass containing less than about 0.015% by weight iron (Fe), and may have a transmissiveness of about 0.9 or greater in the spectrum of interest (e.g., wavelengths from about 300 nm to about 900 nm). In another embodiment, a high strain-point glass, such as borosilicate glass, may be utilized so as to better withstand high temperature processing. For example, the transparent substrate 12 can be a relatively thin sheet of borosilicate glass, such as having a thickness of about 0.5 mm to about 2.5 mm.

The encapsulation substrate 14 defines a connection aperture 15 providing access to the underlying components to collect the DC electricity generated by the photovoltaic device 10. In one particular embodiment, the encapsulation substrate 14 is a glass substrate, such as those discussed above with respect to the transparent substrate 12. For example, in one embodiment, the transparent substrate 12 can be a borosilicate glass having a thickness of about 0.5 mm to about 2.5 mm, while the encapsulation substrate 14 is a low iron float glass having a thickness that is greater than that of the transparent substrate 12 (e.g., about 3 mm to about 10 mm).

The thin film stack 22 in the device 10 can include a plurality of thin film layers positioned on the transparent substrate 12. The thin film stack can define individual photovoltaic cells 20 separated by scribe lines 21. The individual photovoltaic cells 20 are electrically connected together in series. In one particular embodiment, the thin film stack 22 can include a transparent conductive oxide layer (e.g., cadmium stannate or a stoichiometric variation of cadmium, tin, and oxygen; indium tin oxide, etc.) on the transparent substrate 12, an optional resistive transparent buffer layer (e.g., a combination of zinc oxide and tin oxide, etc.) on the transparent conductive oxide layer, an n-type window layer on the resistive transparent buffer layer, an absorber layer on the n-type window layer, and a back contact on the absorber layer. In one particular embodiment, the n-type window layer can include cadmium sulfide (i.e., a cadmium sulfide thin film layer), and/or the absorber layer can include cadmium telluride (i.e., a cadmium telluride thin film layer). Other thin film layers may also be present in the film stack, as desired. Generally, the back contact defines the exposed surface of the thin film stack 22, and serves as an electrical contact of the thin film layers opposite the front contact defined by the transparent conductive oxide layer.

An insulating layer 24 is provided on the thin film stack 22 to isolate the back contact of the thin film stack 22 from the leads 25, 26. The insulating layer 24 generally includes an insulating material that can prevent electrical conductivity therethrough. Any suitable material can be used to produce the insulating layer 24. In one embodiment, the insulating layer 24 can be an insulating polymeric film coated on both surfaces with an adhesive coating. The adhesive coating can allow for adhesion of the insulating layer 24 to the underlying thin film stack 22 and for the adhesion of the leads 25, 26 to the insulating layer 24. For example, the insulating layer 24 can include a polymeric film of polyethylene terephthalate (PET) having an adhesive coating on either surface. The adhesive coating can be, for example, an acrylic adhesive, such as a pressure sensitive acrylic adhesive.

In one particular embodiment, the insulating layer 24 is a strip of insulating material generally oriented in a direction perpendicular to the orientation of the scribe lines 21. The insulating layer 24 can have a thickness in the z-direction suitable to prevent electrical conductivity from the underlying thin film stack 22, particularly the back contact, to any subsequently applied layers. In one particular embodiment, the insulating layer 24 can prevent electrically conductivity between the thin film stack 22 and the leads 25, 26.

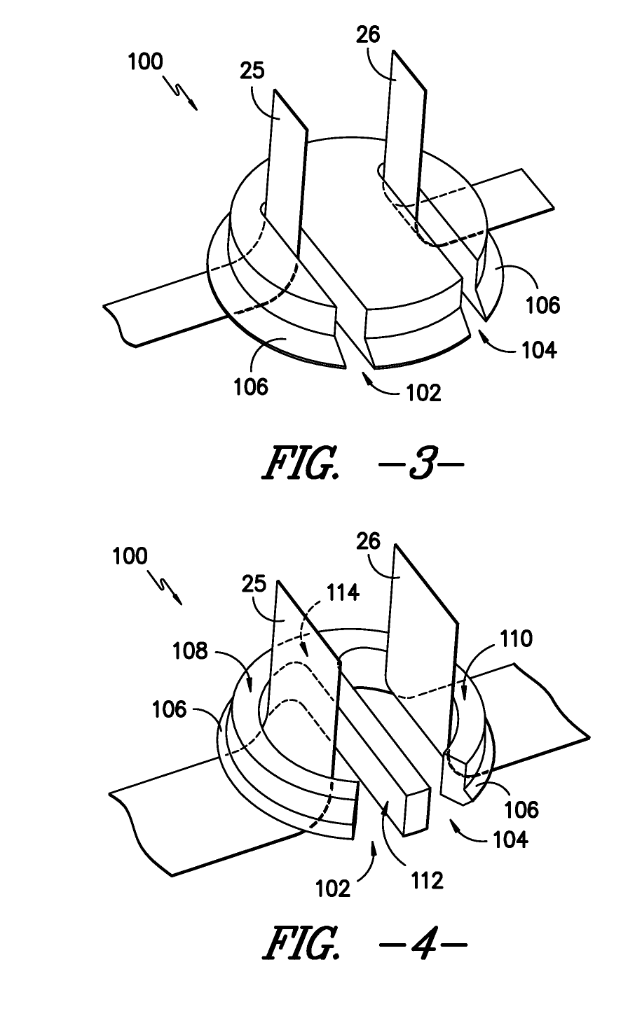

Optionally, an intra-laminate disk layer 35 can be positioned on the insulating layer 24 over an area of the thin film stack 22 to be exposed by the connection aperture 15 of the encapsulation substrate 14, as shown in FIG. 2. For example, the intra-laminate disk layer 35 can extend over a protected area that is equal to or larger than the connection aperture 15 defined by the encapsulation substrate 14. When present, the intra-laminate disk layer 35 can define a substantially circular disk in the x, y plane (which is perpendicular to the z-direction D_{z}). This shape can be particularly useful when the connection aperture 15 in the encapsulation substrate 14 has the same shape in the x, y plane (e.g., circular). As such, the intra-laminate disk layer 35 can be substantially centered with respect to the connection aperture 15 defined by the encapsulation substrate 14. Also, with this configuration, the disk diameter of the intra-laminate disk layer 35 can be larger than the aperture diameter defined by the connection aperture 15. For instance, the disk diameter can be at about 5% larger to about 200% larger than the connection diameter, such as about 10% larger to about 100% larger. However, other sizes and shapes may be used as desired. In certain embodiments, the intra-laminate disk layer can define a thickness, in the z-direction, of about 50 μm to about 400 μm. If too thick, however, the intra-laminate disk layer 35 could lead to de-lamination of the device 10.

The intra-laminate disk layer 35 can, in one embodiment, be a polymeric film, which can serve as a moisture barrier. In one particular embodiment, the film can be a polymeric film, including polymers such as polyethylene, polypropylene, polyethylene terephthalate (PET), ethylene-vinyl acetate copolymer, or copolymers or mixtures thereof. Alternatively, the intra-laminate disk layer 35 can be a sheet of thin glass, e.g., having a thickness of about 0.02 mm to about 0.25 mm (e.g., 0.04 mm to 0.15 mm). When constructed of glass, the intra-laminate disk layer 35 can provide excellent barrier properties to moisture along with providing some structural support to the device 10. It is to be understood that the intra-laminate disk layer 35 could yet instead be in the form of a laminated glass disk, with a glass sheet having a laminate layer thereon being made, for example, of a polymeric film as per above. Such a laminated glass disk could provide the adhesion characteristics of the polymeric film and the barrier properties of the glass, and may also play a role in making the hole region more resistant to hail impact, especially if it is comprised of glass.

In one embodiment, for example, the intra-laminate disk layer 35 can be constructed of a film having a polymeric coating on one or both surfaces. The polymeric coating can include a hydrophobic polymer configured to inhibit moisture ingress through the intra-laminate disk layer 35 and/or around the intra-laminate disk layer 35. In addition, the polymeric coating can help adhere the intra-laminate disk layer 35 to the underlying layers (e.g., the thin film stack 22) and subsequently applied layers (e.g., the adhesive layer 40). In one particular embodiment, the polymeric coating can include a material similar to the adhesive layer 40 in the device (e.g., an ethylene-vinyl acetate copolymer).

The intra-laminate disk layer 35 can be, in one particular embodiment, applied after the insulating layer 24, to result in the embodiment of FIG. 2, where the intra-laminate disk layer 35 is positioned between the insulating layer 24 and the sealing layer 36.

A sealing layer 36 can then be applied on the thin film stack 22 and the insulating layer 24 (and optional intra-laminate disk layer 35, if present), as shown in FIG. 2. When both the sealing layer 36 and the intra-laminate disk layer 35 are present, the sealing layer 36 can help to hold the intra-laminate disk layer 35 in place in the finished PV device 10 by providing the intra-laminate disk layer 35 in a smaller size in the x, y plane (e.g., a smaller diameter) than the sealing layer 36, such that the sealing layer 36 bonds the edges of the intra-laminate disk layer 35 to the thin film stack 22.

Whether or not the intra-laminate disk layer 35 is present, a sealing layer 36 can be positioned where the connection aperture 15 of the encapsulation substrate 14 is located on the device 10, as shown in FIG. 2. The composition of the sealing layer 36 (e.g., a synthetic polymeric material, as discussed below) can be selected such that the sealing layer 36 has a moisture vapor transmission rate that is 0.5 g/m²/24 hr or less (e.g., 0.1 g/m²/24 hr or less, such as 0.1 g/m²/24 hr to about 0.001 g/m²/24 hr). As used herein, the “moisture vapor transmission rate” is determined according to the test method of ASTM F 1249 at a 0.080″ thickness. As such, the sealing layer 36 can form a moisture barrier between the connection aperture 15 in the encapsulation substrate 14 and the thin film stack 22 and define a protected area thereon.

In one embodiment, the sealing layer 36 can be sized to be larger than the connection aperture 15 defined by the encapsulation substrate 14 (e.g., if circular, the sealing layer 36 can have a diameter that is larger than the diameter of the connection aperture 15). In this embodiment, the sealing layer 36 can not only form a moisture barrier between the protected area of the thin film layers 22 and the connection aperture 15, but also can help adhere the encapsulation substrate 14 to the underlying layers of the device 10.

In one particular embodiment, the sealing layer 36 can include a synthetic polymeric material. The synthetic polymeric material can, in one embodiment, melt at the lamination temperature, reached when the encapsulation substrate 14 is laminated to the transparent substrate 12, such that the synthetic polymeric material melts and/or otherwise conforms and adheres to form a protected area on the thin film stack 22 where the connection aperture 15 is located on the device 10. For instance, the synthetic polymeric material can melt at laminations temperatures of about 120° C. to about 160° C.

The synthetic polymeric material can be selected for its moisture barrier properties and its adhesion characteristics, especially between the encapsulation substrate 14 (e.g., a glass) and the back contact layer(s) of the thin film stack 22. For example, the synthetic polymeric material can include, but is not limited to, a butyl rubber or other rubber material. Though the exact chemistry of the butyl rubber can be tweaked as desired, most butyl rubbers are a copolymer of isobutylene with isoprene (e.g. produced by polymerization of about 98% of isobutylene with about 2% of isoprene). One particularly suitable synthetic polymeric material for use in the sealing layer 36 is available commercially under the name HelioSeal® PVS 101 from ADCO Products, Inc. (Michigan Center, Mich.).

The leads 25, 26, in one embodiment, can be applied as a continuous strip over the insulating layer 24 and the sealing layer 36, and then the continuous strip can then be severed to produce the first lead 25 and the second lead 26, as shown in FIG. 2. The leads 25, 26 can be constructed from any suitable material. In one particular embodiment, the leads 25, 26 is a strip of metal foil. For example, the metal foil can include a conductive metal.

Sealing strips 38a, 38b can extend over a portion of the first lead 25 and the second lead 26, respectively. The sealing strips 38a, 38b can be seen in the cross-section shown in FIG. 2, but may be connected to each other, such as in the form of a ring. No matter their exact configuration, the sealing layer 36 can be thermally bonded to the first sealing strip 38a and the second sealing strip 38b to surround the first lead 25 and second lead 26, respectively. Thus, the first sealing strip 38a and the sealing layer 36 can form a circumferential moisture barrier about the first lead 25 to inhibit moisture ingress along the first lead 25 and into the device 10. Likewise, the second sealing strip 38b and the sealing layer 36 can form a circumferential moisture barrier about the second lead 26 to inhibit moisture ingress along the second lead 26 and into the device 10.

The sealing strips 38a, 38b can have any composition as discussed above with respect to the sealing layer 36. Although the composition of the sealing strips 38a, 38b may be selected independently from the each other and/or the sealing layer 36, in one embodiment, the sealing strips 38a, 38b can have the same composition as the sealing layer 36 (e.g., a butyl rubber).

The encapsulation substrate 14 can be adhered to the photovoltaic device 10 via an adhesive layer 40 and, if present, the sealing layer 36 and the sealing strips 38 (or ring). The adhesive layer 40 can be generally positioned over the sealing strips 38, leads 25, 26, sealing layer 36, intra-laminate disk layer 35 (when present), insulating layer 24, and any remaining exposed areas of the thin film stack 22. The adhesive layer 40 can generally define an adhesive gap that generally corresponds to the connection aperture 15 defined by the encapsulation substrate 14. As such, the first lead 25 and second lead 26 can extend through the adhesive gap. The adhesive layer 40 can generally protect the thin film stack 22 and attach the encapsulation substrate 14 to the underlying layers of the device 10. The adhesive layer can be constructed from, for example, ethylene vinyl acetate (EVA), polyvinyl butyral (PVB), silicone based adhesives, or other adhesives which are configured to prevent moisture from penetrating the device.

Finally, a junction box 121 can be attached to the device 10 and positioned to cover the connection aperture 15, such as shown in FIG. 18. The junction box 121 can be configured to electrically connect the photovoltaic device 10 by completing the DC circuit and provide a positive lead wire and a negative lead wire for further collection of the DC electricity produced by the photovoltaic device 10.

Other components and features (not shown) can be included in the exemplary device 10, such as bus bars, external wiring, laser etches, etc. For example, edge sealing layers can be applied around the edges of the device 10 to seal the transparent substrate 12 to the encapsulation substrate 14 along each edge. Additionally, bus bars (not shown) can be attached to connect the photovoltaic cells 20 of the thin film stack 22 to the first lead 25 and second lead 26. Since the photovoltaic cells 20 are connected to each other in series, the bus bars can serve as opposite electrical connections (e.g., positive and negative) on the photovoltaic device 10.

Methods of manufacturing the devices 10 of FIGS. 1, 2, 14, and 18 and the support inserts 100 of FIGS. 3-13 and 15-17 are also encompassed by the present disclosure. Additionally, methods are provided for positioning the support inserts 100 of FIGS. 3-13 and 15-17 into a photovoltaic device (e.g., the devices 10 of FIGS. 1, 2, 14, and 18).

In one embodiment, for example, a method is generally provided for adhering a support insert within a connection aperture defined in an encapsulating substrate of a photovoltaic device that has a first lead, with the connection aperture having a perimeter defined by an aperture wall of the encapsulating substrate. The method can include threading the first lead through the connection aperture; positioning a support insert within the connection aperture such that the first lead is still able to extend through the connection aperture; and injecting an adhesive composition into a channel opening of the support insert such that the adhesive composition flows through a channel defined by the support insert to bond the support insert within the connection aperture.

In another embodiment, the method can include threading the first lead through the connection aperture; positioning a support insert within the connection aperture such that the first lead is able to extend through the connection aperture, wherein the support insert defines a plug portion positioned within the connection aperture and a first platform extending over the back surface of the encapsulation substrate and forming a first reservoir therebetween; and injecting an adhesive composition into a channel opening in the support insert such that the adhesive composition flows through a channel in the support insert out of a first reservoir opening and into the first reservoir to bond the first platform of the support insert to the back surface of the encapsulating substrate. The support insert can further define a second platform, wherein the support insert is positioned such that the plug portion is within the connection aperture and the first platform and the second platform extend over a back surface of the encapsulation substrate. A junction box can then be mounted over the first platform and the second platform of the support insert, and attached to the first lead to the junction box.

Kits are also disclosed that generally include a support insert (e.g., any of the support inserts 100 of FIGS. 3-13 and 15-17), an encapsulation substrate defining a connection aperture, and optionally a junction box or other components of the devices 10 of FIGS. 1, 2, 15, and 17. For example, the kit for use with a photovoltaic device can include an encapsulation substrate defining a connection aperture having a perimeter defined by an aperture wall of the encapsulation substrate, and a support insert configured to be coupled within the connection aperture of the encapsulation substrate. The support insert can be configured such that when coupled with the photovoltaic device, the first lead is capable of extending through the connection aperture.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method of adhering a support insert within a connection aperture defined in an encapsulating substrate of a photovoltaic device that has a first lead, the connection aperture having a perimeter defined by an aperture wall of the encapsulating substrate, the method comprising:
threading the first lead through the connection aperture;
positioning a support insert within the connection aperture such that the first lead is still able to extend through the connection aperture, wherein the support insert defines a channel within its construction, the channel extending from a channel opening in the support insert to an exit port; and,
injecting an adhesive composition into the channel opening such that a first amount of the adhesive composition flows through the channel and out of the exit port to bond the support insert within the connection aperture.

2. The method as in claim 1, wherein the exit port is located on a side of the support insert such that the first amount of the adhesive composition that flows through the channel and out of the exit port bonds the side of the support insert to the aperture wall of the encapsulating substrate.

3. The method as in claim 2, wherein the channel splits within the construction of the support insert such that the channel extends from the channel opening to the exit port and to an inner opening such that injecting the adhesive composition into the channel opening results in the first amount of the adhesive composition flowing through the channel and out of the exit port and a second amount of adhesive composition flowing out of the inner opening, wherein the second amount of the adhesive composition flowing out of the inner opening bonds to an underlying layer of the photovoltaic device.

4. The method as in claim 1, wherein the exit port is located opposite of the channel opening on the support insert such that the first amount of the adhesive composition flows through the channel and out of the exit port to bond the support insert to an underlying layer of the photovoltaic device.

5. The method as in claim 1, wherein the support insert defines a plug portion positioned within the connection aperture and a flange extending over the back surface of the encapsulation substrate.

6. The method as in claim 5, wherein the connection aperture defines a depth from the back surface to the transparent substrate, and wherein the plug portion extends a distance of about 5% to about 75% of the depth of the connection aperture.

7. The method as in claim 6, wherein the exit port is located opposite of the channel opening on the support insert such that first amount of the adhesive composition flows through the channel and out of the exit port to bond the support insert to an underlying layer of the photovoltaic device, the method further comprising:
forming an adhesive plug positioned between the plug portion of the support insert and the transparent substrate.

8. The method as in claim 5, wherein the flange of the support insert defines a first platform and a second platform, wherein the support insert is positioned such that the plug portion is within the connection aperture and the first platform and the second platform extend over a back surface of the encapsulation substrate.

9. The photovoltaic device as in claim 8, further comprising:
mounting a junction box over the first platform and the second platform of the support insert; and,
attaching the first lead to the junction box.

10. The photovoltaic device as in claim 8, wherein the first platform defines a first reservoir between the first platform and the back surface of the encapsulation substrate, and wherein the second platform defines a second reservoir between the second platform and the back surface of the encapsulation substrate, wherein the channel splits within the construction of the support insert such that the channel extends from the channel opening to a first reservoir opening and a second reservoir opening such that injecting the adhesive composition into the channel opening results in a first reservoir portion of the adhesive composition flowing through the channel and out of the first reservoir opening and a second reservoir portion flowing through the channel and out of the second reservoir opening such that the first reservoir portion flowing out of the first reservoir opening bonds the first platform to the back surface of the encapsulation substrate and the second reservoir portion flowing out of the second reservoir opening bonds the second platform to the back surface of the encapsulation substrate.

11. The method as in claim 1, wherein the support insert has a support thickness and the encapsulation substrate has a substrate thickness, and wherein the support thickness is equal to or less than the substrate thickness such that the support insert does not extend beyond an exposed surface defined by the encapsulation substrate.

12. The method as in claim 1, wherein the support insert defines a lip.

13. The method as in claim 12, wherein the lip extends perimetrically about the support insert.

14. The method as in claim 12, further comprising:
coupling the lip of the support insert with a groove defined in the aperture wall of the encapsulation substrate.

15. The method as in claim 1, wherein the support insert defines a first slot, and wherein the support insert is positioned within the connection aperture such that the first lead is extends through the first slot.

16. A method of adhering a support insert within a connection aperture defined in an encapsulating substrate of a photovoltaic device that has a first lead, the connection aperture having a perimeter defined by an aperture wall of the encapsulating substrate, the method comprising:
threading the first lead through the connection aperture;
positioning a support insert within the connection aperture such that the first lead is able to extend through the connection aperture, wherein the support insert defines a plug portion positioned within the connection aperture, wherein the support insert further defines a first platform extending over the back surface of the encapsulation substrate and forming a first reservoir therebetween; and,
injecting an adhesive composition into a channel opening in the support insert such that a first portion of the adhesive composition flows through a channel in the support insert out of a first reservoir opening and into the first reservoir to bond the first platform of the support insert to the back surface of the encapsulating substrate.

17. The method as in claim 16, wherein the support insert further defines a second platform, wherein the support insert is positioned such that the plug portion is within the connection aperture and the first platform and the second platform extend over a back surface of the encapsulation substrate.

18. The photovoltaic device as in claim 17, further comprising:
mounting a junction box over the first platform and the second platform of the support insert; and,
attaching the first lead to the junction box.

19. The photovoltaic device as in claim 16, wherein the second platform defines a second reservoir between the second platform and the back surface of the encapsulation substrate, wherein the channel splits within the construction of the support insert such that the channel extends from the channel opening to the first reservoir opening and a second reservoir opening such that injecting the adhesive composition into the channel opening results in a first reservoir portion of the adhesive composition flowing through the channel and out of the first reservoir opening and a second reservoir portion flowing through the channel and out of the second reservoir opening such that the second reservoir portion bonds the second platform to the back surface of the encapsulation substrate.

20. The method as in claim 16, wherein the channel splits within the construction of the support insert such that the channel extends from the channel opening to the first reservoir opening and to an inner opening such that injecting the adhesive composition into the channel opening results in the a first reservoir portion flowing through the channel and out of the first reservoir opening and the first portion flowing through the channel and out of the inner opening, wherein the first portion flowing out of the inner opening bonds to an underlying of the photovoltaic device.
